(19) United States
(12) Patent Application Publication
(10) Pub. No.: US 2021/0305318 A1
(43) Pub. Date: Sep. 30, 2021

(54) MEMORY DEVICE WITH IMPROVED PHASE CHANGE MATERIAL NUCLEATION RATE

(71) Applicant: INTEL CORPORATION, Santa Clara, CA (US)

(72) Inventors: DAN GEALY, Kuna, ID (US); KUMAR R. VIRWANI, San Jose, CA (US)

(73) Assignee: INTEL CORPORATION, Santa Clara, CA (US)

(21) Appl. No.: 16/834,644

(22) Filed: Mar. 30, 2020

(51) Int. Cl. H01L 27/24; H01L 45/00; G11C 13/00

(52) U.S. Cl. CPC H01L 27/2481; H01L 45/141; H01L 45/145; H01L 45/1616; G11C 13/0028; H01L 45/06; G11C 13/0004; G11C 13/0026

(57) ABSTRACT

A memory cell design is disclosed. The design is particularly well-suited for three-dimensional cross-point (3D X-point) memory configurations. Various embodiments of the memory cell design include a stack of layers having a phase change layer or phase change region that includes nitrogen. The presence of the nitrogen increases crystallization rates of the phase change material during transition from an amorphous state to crystalline state, thus increasing the overall speed of the memory device. In some embodiments, the phase change layer includes a small amount of nitrogen homogenously dispersed within the layer. In some other embodiments, the phase change layer includes one or more regions having nitrogen introduced during the deposition process. In some other embodiments, separate material layers that include nitrogen are provided on one or more sides of the phase change layer.

### BACKGROUND

As electronic devices continue to become smaller and more complex, the need to store more data and access that data quickly similarly grows. New memory architectures have been developed that use an array of memory cells with so-called phase change materials (PCM) that have variable bulk resistance, allowing the resistance value to dictate whether a given memory cell stores a logic ‘0’ or a logic ‘1’. Many challenges exist when fabricating such PCM-based memory architectures.

### BRIEF DESCRIPTION OF THE DRAWINGS

Features and advantages of embodiments of the claimed subject matter will become apparent as the following Detailed Description proceeds, and upon reference to the Drawings, in which:

FIG. 1A illustrates a cross-section view of a portion of an array of memory cells, in accordance with some embodiments of the present disclosure.

FIGS. 1B and 1C illustrate cross-section views of a larger portion of the array of memory cells shown in FIG. 1A, in accordance with some embodiments of the present disclosure. The views of FIGS. 1B and 1C are orthogonal with respect to each other.

FIG. 2 illustrates a cross-section view of a chip package containing one or more memory dies, in accordance with some embodiments of the present disclosure.

FIG. 3 illustrates a cross-section view of a portion of a memory device structure generated during a fabrication process, in accordance with some embodiments of the present disclosure.

FIG. 4 illustrates various examples of a phase change region that can be formed during the fabrication process noted in FIG. 3, in accordance with some embodiments of the present disclosure.

FIG. 5 illustrates a cross-section view of a portion of a memory device structure generated later in the fabrication process noted in FIGS. 3 and 4, in accordance with some embodiments of the present disclosure.

FIG. 6 illustrates a cross-section view of a portion of a memory device structure generated later in the fabrication process noted in FIG. 5, in accordance with some embodiments of the present disclosure.

FIG. 7 illustrates a cross-section view of a portion of a memory device structure generated later in the fabrication process noted in FIG. 6, in accordance with some embodiments of the present disclosure.

FIG. 8 is a data plot showing X-ray diffraction data for a phase change material sample without any added nitrogen.

FIG. 9 is a data plot showing X-ray diffraction data for a phase change material sample with added nitrogen, in accordance with an embodiment of the present disclosure.

FIG. 10 is a method for forming a phase change region of a memory device, in accordance with an embodiment of the present disclosure.

FIG. 11 is a method for forming a phase change region of a memory device, in accordance with another embodiment of the present disclosure.

FIG. 12 is a method for forming a phase change region of a memory device, in accordance with another embodiment of the present disclosure.

FIG. 13 illustrates an example electronic device that can include one or more of the embodiments of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles, and some features may have surface topology or otherwise be non-smooth, given real world limitations of the processing equipment and techniques used.

### DETAILED DESCRIPTION

A memory cell design is disclosed. The design is particularly well-suited for three-dimensional cross-point (3D X-point) memory configurations, although other memory applications that can benefit will be apparent. Various embodiments of the memory cell design include a stack of layers having a phase change layer or phase change region that includes nitrogen. The presence of the nitrogen, particularly at the interfaces between the phase change layer and the neighboring upper and lower electrodes, increases crystallization rates of the phase change material during transition from an amorphous state to crystalline state, thus increasing the overall speed of the memory device. Numerous methods of introducing the nitrogen are described herein. In one embodiment, a phase change layer is deposited that includes a relatively small amount of nitrogen homogenously dispersed within the layer. In another embodiment, a phase change layer is deposited that includes one or more regions having nitrogen introduced during the deposition process. In another embodiment, separate material layers that include nitrogen are provided on one or more sides of the phase change layer, such as the first one to three monolayers and the last one to three monolayers of the phase change layer. The separate nitrogen-containing material layers, or nitrogen-containing portions of the phase change layer as the case may be, may include refractory nitride compounds. Such nitrogen-containing layers or portions may be deposited using various deposition methods such as, for example, physical vapor deposition (PVD), chemical vapor deposition (CVD), plasma-enhanced CVD (PECVD), and atomic layer deposition (ALD). Note that, in some embodiments, a nitrogen flow can be turned on as needed during the deposition of the phase change layer, such as for example a nitrogen flow rate of 0.5 to 1.5 sccm for a given period of time and at a given deposition temperature (e.g., 5 to 50 seconds at 150° C. to 350° C.). In some examples, a nitrogen containing precursor is added during either the first few reaction cycles or the last few reaction cycles. As will be appreciated in light of this disclosure, each of the discussed embodiments that introduce nitrogen into the phase change region increases at least the write speed when selecting one or more memory cells. Numerous configurations and embodiments will be apparent.

### General Overview

As noted above, there are several non-trivial issues associated with fabricating memory arrays based on bulk resistance changes of a phase-change material. In some cases, the phase change material is included as a layer in a multi-layer stack that further includes a selector layer as well as electrode material layers that sandwich each of the phase change material and the selector layer. This multi-layer stack is then etched into an array of smaller individual stacks. Each individual stack can be used as one memory cell in the overall memory array. Numerous levels (or decks) of memory cells make up the memory array, such that even decks of memory cells alternate with odd decks of memory cells. When selecting a particular memory cell in the array, a potential (voltage) is applied across the corresponding word line and bit line that intersect over the selected memory cell to apply current through the selected memory cell. However, the speed of accessing memory cells on odd decks is typically slower than the speed of accessing memory cells on even decks due to the memory cell geometry and/or the nucleation and growth kinetics of the phase change material during its crystallization process. This occurs because nucleation within the phase change material proceeds from opposite sides of the phase change layer on alternating decks within the memory array, yet the nucleation rate is different for the opposite sides.

To this end, techniques and memory cell designs are provided herein to help eliminate or otherwise reduce the degree of such asymmetrical access issues, such that the speed of accessing memory cells of the odd decks is more on par with the speed of accessing memory cells of the even decks. In some example embodiments, memory cell structures are provided that have nitrogen added to the phase change region of the memory cell, at the one or both interfaces between the phase change region and the adjacent upper and lower electrodes. The nitrogen may be added directly to the phase change material (in situ) as that material is deposited, or added in separate material layers that are adjacent to the phase change layer. The introduction of nitrogen with the phase change material is typically avoided since the nitrogen can corrupt the phase change material and inhibit its ability to transition between amorphous and crystalline phases. However, and as will be appreciated in light of this disclosure, introducing a small amount of nitrogen with the phase change material (e.g., less than 2% atomic weight) actually improves the crystallization rate of the phase change material leading to faster operating speeds of the memory device. In some embodiments, thin material layers (e.g., less than 20 Å thick, such as one to five monolayers) that include refractory nitrides can be deposited adjacent to one or both upper and lower surfaces of the phase change layer, where the refractory nitride includes anywhere from 1% to 50% nitrogen by atomic weight. A process knob can turn on a nitrogen flow or source to selectively integrate nitrogen into the phase change layer being deposited, as will be appreciated. In some other embodiments, nitrogen can be introduced after the phase change layer is etched to dope exposed sidewalls of the phase change layer. The nitrogen may diffuse inwards from the sidewalls of the phase change layer. Accordingly, vertically-oriented regions (e.g., orthogonal to the planes of the word lines and bit lines) of varying nitrogen content can be formed within the phase change layer.

In one example embodiment, a memory device includes a plurality of conductive bit lines, a plurality of conductive word lines, and a set of memory cells included in a memory array. Each of the memory cells is located between a corresponding bit line of the plurality of conductive bit lines and a corresponding word line of the plurality of conductive word lines. Each of the memory cells includes a stack of layers that includes a phase change layer, and one or more of the phase change layers includes nitrogen. In such example embodiments, the phase change layer is effectively a continuous layer that includes nitrogen at one or more portions of the phase change layer.

In another embodiment, a memory device includes a plurality of conductive bit lines, a plurality of conductive word lines, and a set of memory cells included in a memory array. Each of the memory cells is located between a corresponding bit line of the plurality of conductive bit lines and a corresponding word line of the plurality of conductive word lines. Each of the memory cells includes a stack of layers, where one or more of the stacks of layers includes a material layer having nitrogen at the interface between an electrode and a phase change layer. So, for instance, the phase change layer can be on the material layer, and the material layer can be on an electrode layer.

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate the presence of nitrogen within the phase change material layer or may indicate the presence of additional material layers including nitrogen that are adjacent to the phase change material layer particularly near where the phase change material interfaces one or more electrodes, as variously described herein. Numerous configurations and variations will be apparent in light of this disclosure.

Various operations may be described as multiple discrete actions or operations in turn, in a manner that is most helpful in understanding the claimed subject matter. However, the order of description should not be construed as to imply that these operations are necessarily order dependent. In particular, these operations may be performed in a different order from the described embodiment. Various additional operations may be performed, and/or described operations may be omitted in additional embodiments. When used to describe a range of dimensions, the phrase “between X and Y” represents a range that includes X and Y.

It should be readily understood that the meaning of “above” and “over” in the present disclosure should be interpreted in the broadest manner such that “above” and “over” not only mean “directly on” something but also include the meaning of over something with an intermediate feature or a layer therebetween. Additionally, the meaning of “on” in the present disclosure should be interpreted to mean directly on something (i.e., having no intermediate feature or layer therebetween.)

Further, spatially relative terms, such as “beneath,” “below,” “lower,” “above,” “upper,” and the like, may be used herein for ease of description to describe one element or feature's relationship to another element (s) or feature (s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A monolayer is a layer that consists of a single layer of atoms of a given material. A layer can extend over the entirety of an underlying or overlying structure or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer. A substrate can be a layer, can include one or more layers therein, and/or can have one or more layer thereupon, thereabove, and/or therebelow.

Memory Array Architecture

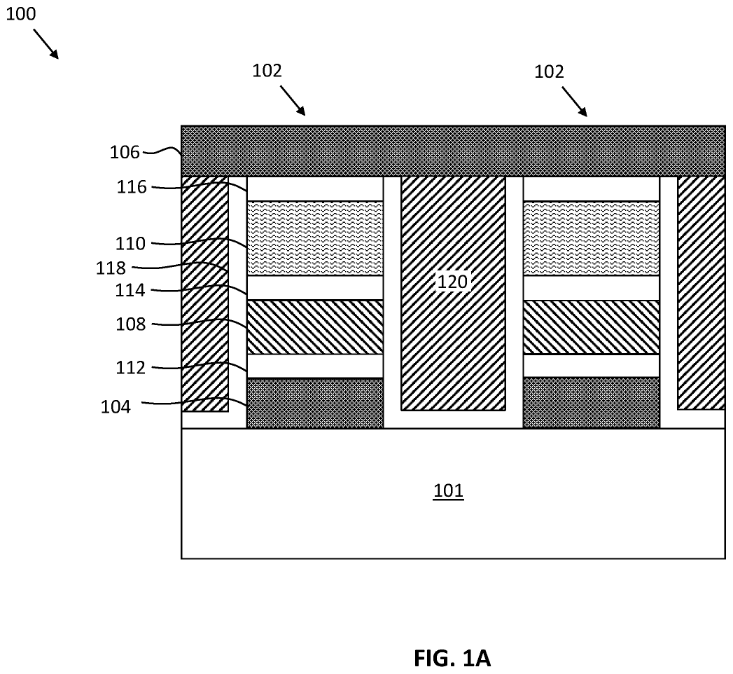

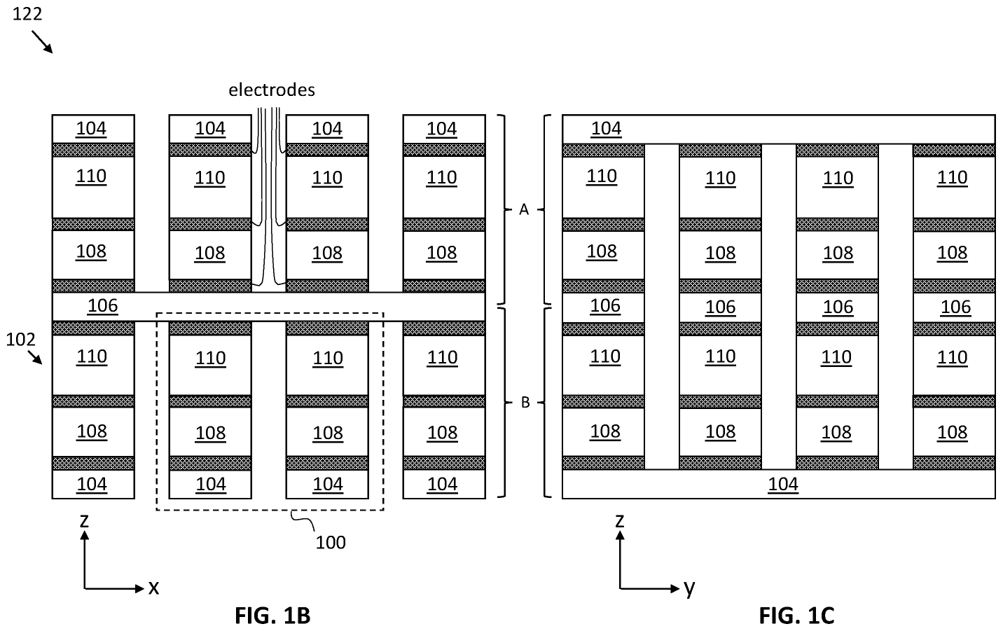

FIG. 1A illustrates a cross-section view of a portion 100 of a memory cell array over a substrate 101, according to an embodiment. Portion 100 includes adjacent memory cells 102 each including a stack of material layers sandwiched between a particular word line 104 and bit line 106, according to some embodiments. A potential is applied across a particular word line 104 and a particular bit line 106 in order to read from or program the memory cell 102 at the intersection of (between) the chosen word line 104 and chosen bit line 106. In this manner, word lines 104 and bit lines 106 provide top and bottom electrodes to memory cells 102. As noted in this example, word lines 104 run orthogonal to bit lines 106. Word lines 104 and bit lines 106 may be made of any conductive material, such as a metal, metal alloy, or polysilicon. In some examples, word lines 104 and bit lines 106 are made of tungsten, silver, aluminum, gold, carbon, or copper, or a multi-layer structure comprising such materials (e.g., tungsten and carbon layers).

Each memory cell 102 includes a stack of layers having at least one selector layer 108, at least one phase change layer 110, and one or more intermediate electrodes 112, 114, 116 according to an embodiment. Selector layer 108 includes a material that acts similarly to a diode and is highly resistive until a threshold potential is applied across it, at which point its resistance lowers and current passes through it, according to some embodiments. Examples of materials for selector layer 108 include chalcogenide-based alloys, such as germanium selenide or germanium antimony selenide doped with arsenic. Any number of chalcogenides can be used to provide a standard selector layer 108. Proprietary selectors may be used as well in conjunction with the techniques provided herein, as will be appreciated.

As used herein, the term “selector layer” refers to the standard meaning of that phrase in the context of memory devices, and in some cases refers to one or more layers that includes a material capable of acting as a selector. For example, at least one selector layer 108 of the memory cell array may include a chalcogenide alloy, such as chalcogenide doped with arsenic. The selector layer 108 effectively provides access to the bit (logic ‘0’ or ‘1’) stored by the phase change layer 110.

Phase change layer 110 includes a material that changes its phase to either represent a logic ‘0’ or a logic ‘1’ for the given memory cell 102. As used herein, the term “phase change layer” generally refers to the standard meaning of that phrase in the context of memory devices, and in some cases refers to one or more layers that includes a metalloid alloy, although there may be some nitrogen included as well as will be explained in turn. The metalloids include boron (B), silicon (Si), germanium (Ge), arsenic (As), antimony (Sb), and tellurium (Te). Although technically a metalloid, polonium (Po) is radioactive and thus unlikely to be included. In some embodiments, phase change layer 110 includes chalcogenide, which comprises an alloy of germanium, arsenic, antimony, and tellurium, such as germanium telluride (GeTe), germanium antimony telluride (GeSbTe, or sometimes called GST), GeTe alloyed with bismuth (GeBiTe), or GeSbTe alloyed with indium (GeInSbTe), to name a few non-limiting examples. Moreover, note the stoichiometry of such compounds may vary from one embodiment to the next, and such compounds represented without stoichiometric coefficients or values are intended to represent all forms of that compound. Further note that, in this particular disclosure, the terms compound and alloy may be used interchangeably, as will be appreciated.

In one example, chalcogenide is used as the phase change material and can change between an amorphous state or phase and a crystalline state or phase based on applied temperature or passing a current through the material. In its amorphous state, the chalcogenide elements are disorganized, and the material is highly resistive. In its crystalline state, the chalcogenide elements are ordered, and the material becomes less resistive. For the purpose of the memory bit, the amorphous state of the chalcogenide may be read as a logic ‘0’ and the crystalline state of the chalcogenide may be read as a logic ‘1’, according to an embodiment.

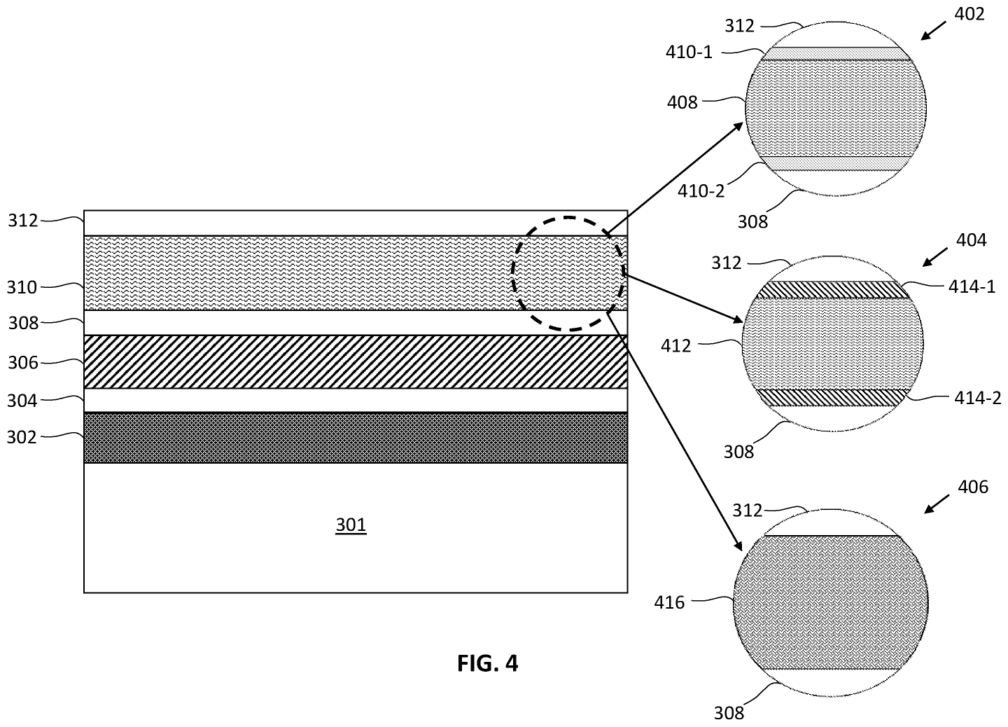

According to some embodiments, phase change layer 110 includes a small amount of nitrogen to enhance the ability for the material to transition between amorphous and crystalline states. The nitrogen may be homogeneously provided throughout a thickness of phase change layer 110, according to some embodiments. In some other embodiments, the nitrogen is present in some portions of phase change layer 110 and not in other portions of phase change layer 110, such as the case where there is nitrogen at the top (end) and bottom (beginning) of the phase change layer 110 but not in the middle portion of the phase change layer 110. In still other embodiments, a concentration gradient of nitrogen is present through at least a portion of the thickness of phase change layer 110, such as the case where the concentration of nitrogen is greater at the interfaces with electrodes 114 and 116. In some embodiments, phase change layer 110 includes one or more regions parallel to the planes of bit lines 106 and word lines 104 and one or more regions orthogonal to the planes of bit lines 106 and word lines 104, where each of the regions may include varying amounts of nitrogen. Some other embodiments include one or more separate material layers that include nitrogen under and/or above (and contacting) phase change layer 110. In this manner, note that phase change layer 110 may be referred to herein as a structure, wherein that structure may be a single continuous layer that has at least one graded element (such as nitrogen) or alternatively may be multiple discrete layers, or alternatively may be a combination of graded and discrete layers. Such example embodiments are described in more detail with reference to FIG. 4.

Each of one or more intermediate electrodes 112, 114, and 116 provide enhanced ohmic contact for selector layer 108 and phase change layer 110, and also separate the highly reactive materials in both selector layer 108 and phase change layer 110 from each other. Each of one or more intermediate electrodes 112, 114, and 116 may comprise carbon, though other conductive materials may be used as well. For instance, and in a more general sense, electrodes 112, 114, and 116 can comprise any materials that electrically connect operational elements of the memory cell but that are nonreactive or otherwise inhibit reactions among the selector and phase change materials. For example, where the selector layer 108 and the phase change layer 110 comprise chalcogenide materials, it may be advantageous to place non-reactive conductors therebetween to prevent interdiffusion of their materials, and also between these elements and their respective neighboring conductive bit lines and word lines, particularly conductive lines formed of metallic material. Examples of suitable electrode materials include one or more conductive and semi-conductive materials such as, for example: carbon; polysilicon; metals such as aluminum, copper, chromium, cobalt, nickel, ruthenium, silver, platinum, gold, tantalum, and tungsten; conductive metal nitrides such as titanium nitride, tantalum nitride, tungsten nitride, and tantalum carbon nitride; conductive metal silicides and germanides such as tantalum silicides, tungsten silicides, nickel silicides or germanide, cobalt silicides and titanium silicides; and conductive metal oxides such as ruthenium oxide.

Sidewalls of each memory cell 102 are protected by a liner structure 118. Although liner structure 118 is illustrated as being a single continuous film, liner structure 118 may be deposited as a series of material films or layers over the course of a plurality of deposition cycles. Dielectric materials, such as silicon nitride, may be deposited as part of liner structure 118. A fill dielectric 120 is used between adjacent memory cells 102. In some embodiments, fill dielectric can be any dielectric material, such as silicon oxide.

FIGS. 1B and 1C illustrate cross-section views of a memory array 122, according to some embodiments. Portion 100 of memory array 122 includes two memory cells 102 of the plurality of arrayed memory cells. The cross-section views are taken orthogonally to one another in memory array 122. As can be seen, memory array 122 includes a plurality of memory cells 102 arranged in arrays A and B stacked in the Z-direction to form a 3D memory structure. The array 122 includes an ordered arrangement of rows and columns of memory cells 102 in the XY plane as illustrated in FIGS. 1B and 1C. Other ordered arrangements are possible as well, as will be appreciated. Each memory cell 102 generally includes a selector layer 108, a phase change layer 110, and a plurality of electrodes (which are depicted as patterned bars in FIGS. 1B and 1C) that sandwich each of selector layer 108 and phase change layer 110. According to some embodiments, sidewalls of each memory cell 102 are protected by a liner structure (such as shown in FIG. 1A).

As can be further seen, memory array 122 includes a plurality of word lines 104 and bit lines 106 used to address a particular memory cell 102 with the stack. As noted in this example, word lines 104 run orthogonal to bit lines 106 and memory array 122 alternates between word lines 104 and bit lines 106 in the Z-direction. With further reference to FIGS. 1B and 1C, word lines 104 run along the Y-direction (into and out of the page in FIG. 1B), and bit lines 106 run along the X-direction (into and out of the page in FIG. 1C). As will be appreciated, the identification of a bit line does not limit the ability for the same conductive line to also act as a word line and visa-versa. Whether a particular conductive line acts as a bit line or a word line can depend on the application.

It will be appreciated that the number of memory cells 102 illustrated is purely used as an example, and that any number of memory cells 102 can be used in each tier, and that any number of tiers in the Z-direction can be used as well. According to some embodiments, the height in the Z-direction of a given memory cell 102 is between about 100 nm and about 150 nm. According to some example embodiments, the width in either the X-direction or the Y-direction of a given memory cell 102 is between about 10 nm and about 20 nm. The width may be the same in both the X-direction and the Y-direction. Any number of memory cell geometries can be utilized, as will be appreciated.

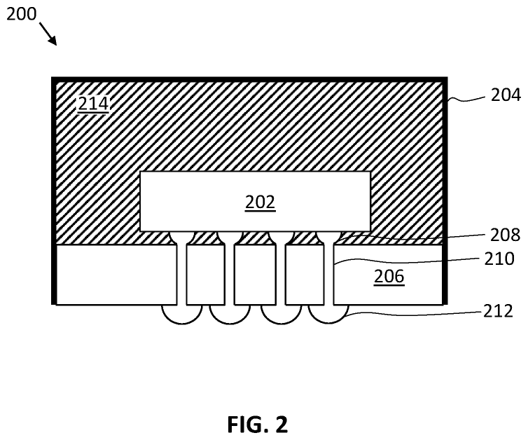

FIG. 2 illustrates an example embodiment of a chip package 200. As can be seen, chip package 200 includes one or more dies 202. Chip package 200 may be a memory device when one or more dies 202 include one or more memory dies, whether it be a dedicated memory die, or some other die that has a memory portion juxtaposed to other functional circuitry of the die (e.g., such as a processor that has on-board memory). Die 202 may include any number of memory arrays 122 as well as any other circuitry used to interface with the memory arrays, in some example configurations. In still other embodiments, memory arrays 122 may be present on one die 202 and other circuitry used to interface (e.g., cell selection circuitry, readout circuitry, and programming circuitry) with die 202 is on another die within chip package 200.

As can be further seen, chip package 200 includes a housing 204 that is bonded to a package substrate 206. The housing 204 may be any standard or proprietary housing, and provides, for example, electromagnetic shielding and environmental protection for the components of chip package 200. The one or more dies 202 may be conductively coupled to a package substrate 206 using connections 208, which may be implemented with any number of standard or proprietary connection mechanisms, such as solder bumps, ball grid array (BGA), pins, or wire bonds, to name a few examples. Package substrate 206 may be any standard or proprietary package substrate, but in some cases includes a dielectric material having conductive pathways (e.g., including conductive vias and lines) extending through the dielectric material between the faces of package substrate 206, or between different locations on each face. In some embodiments, package substrate 206 may have a thickness less than 1 millimeter (e.g., between 0.1 millimeters and 0.5 millimeters), although any number of package geometries can be used. Additional conductive contacts 212 may be disposed at an opposite face of package substrate 206 for conductively contacting, for instance, a printed circuit board. One or more vias 210 extend through a thickness of package substrate 206 to provide conductive pathways between one or more of connections 208 to one or more of contacts 212. Vias 210 are illustrated as single straight columns through package substrate 206 for ease of illustration, although other configurations can be used (e.g., damascene, dual damascene, through-silicon via, to name a few example configurations). In still other embodiments, vias 210 are fabricated by multiple smaller stacked vias, or are staggered at different locations across package substrate 206. In the illustrated embodiment, contacts 212 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 212, to inhibit shorting.

In some embodiments, a mold material 214 may be disposed around the one or more dies 202 included within housing 204 (e.g., between dies 202 and package substrate 206 as an underfill material, as well as between dies 202 and housing 204 as an overfill material). Although the dimensions and qualities of the mold material 214 can vary from one embodiment to the next, in some embodiments, a thickness of mold material 214 is less than 1 millimeter. Example materials that may be used for mold material 214 include epoxy mold materials, as suitable. In some cases, the mold material 214 is thermally conductive so that heat is propagated to the housing and/or heat sink (if present), in addition to being electrically insulating.

Phase Change Region with Nitrogen

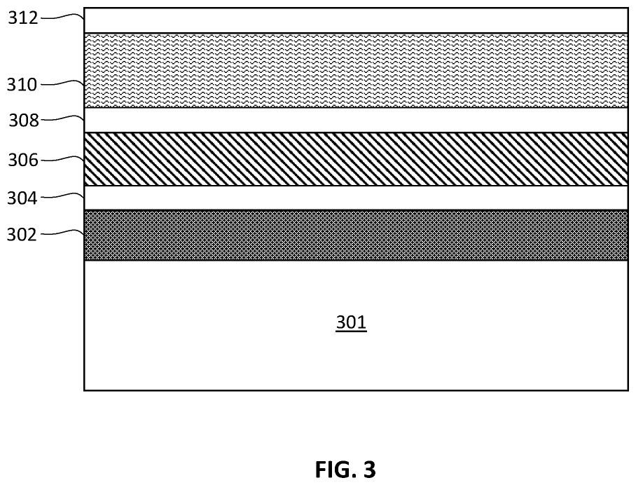

FIGS. 3 through 7 illustrate cross-section views of different stages of a fabrication process for portion 100 of memory array 122, according to some embodiments of the present disclosure. The various layers and structures illustrated in FIGS. 3 through 7 are not intended to be drawn to scale but are illustrated in a particular fashion for clarity. Some intermediate processes may be performed that are not explicitly illustrated, as will be appreciated (e.g., such as polishing and cleaning processes, or other standard processing).

FIG. 3 illustrates a stack of material layers deposited over a substrate 301, according to some embodiments. Substrate 301 may be any suitable substrate material for forming additional material layers over it. In some embodiments, substrate 301 includes a semiconductor material such as silicon, germanium, silicon germanium, gallium arsenide, or indium phosphide. Substrate 301 may include one or more insulating layers at its top surface, such as silicon oxide or silicon nitride, or buried below a top semiconductor layer such as in semiconductor-on-insulator substrate configurations.

A first conductive layer 302 may be deposited over the top surface of substrate 301. First conductive layer 302 may be a metal, such as tungsten, silver, aluminum, titanium, cobalt, copper, or an alloy. In some embodiments, first conductive layer 302 has a sufficient thickness (e.g., 1 to 50 nm thick) to propagate signals after first conductive layer 302 has been patterned into word lines or bit lines.

A first electrode layer 304 may be deposited on first conductive layer 302, followed by at least one selector layer 306, and a second electrode layer 308. Each of first electrode layer 304 and second electrode layer 308 may include, for example, aluminum, carbon, copper, platinum, titanium, titanium nitride, tantalum nitride, tungsten, and/or any other conductive material that enhances the ohmic contact being made to at least one selector layer 306. In one example, first electrode layer 304 and second electrode layer 308 comprise carbon.

Next, at least one phase change region 310 is formed over second electrode layer 308. As can be further seen, a third electrode layer 312 may also be deposited over phase change region 310 to provide an ohmic contact to phase change region 310. Third electrode layer 312 may similarly comprise carbon. In some embodiments, each of electrode layers 304, 308, and 312 comprise the same material.

Phase change region 310 may include one phase change layer that includes a chalcogenide, such as GeInSbTe, with added nitrogen. In another embodiment, phase change region 310 includes a phase change layer and additional material layers, where the additional material layers include nitrogen.

FIG. 4 illustrates another view of the stack of material layers from FIG. 3, but with an emphasis on various example configurations for phase change region 310, according to some embodiments. Accordingly, phase change structures 402, 404, and 406 represent different example configurations of phase change region 310. In general, and as previously explained, phase change region 310 may be a single continuous layer having one or more graded elements such as nitrogen (such as the case wherein the nitrogen process knob is turned on and then off at select times during the deposition process that forms phase change layer 310), or alternatively may including multiple discrete layers, or some combination of graded and discrete layers. Numerous such configurations will be apparent in light of this disclosure.

Phase change structure 402 includes a phase change layer 408 sandwiched between additional material layers 410-1 and 410-2, according to an embodiment. Phase change layer 408 may include a chalcogenide, such as GeInSbTe or GeSbTe. In some embodiments, phase change layer 408 is deposited using sputtering (physical vapor deposition), CVD, PECVD, or ALD and has a thickness between about 5 nm and about 50 nm.

According to some such embodiments, additional material layers 410-1 and 410-2 include refractory nitrides having materials from groups Ma, IVa, IVb, Vb, VIIb, or VIIIb. Additional material layers 410-1 and 410-2 may include, for instance, nitrides of any one of the metals zirconium (Zr), hafnium (Hf), niobium (Nb), tantalum (Ta), manganese (Mn), or aluminum (Al). According to some embodiments, material layers 410-1 and 410-2 include anywhere from 1%-50% nitrogen by atomic % and are deposited to be very thin, such as less than 20 Å or between 4 Å and 20 Å. In some embodiments, sputtering techniques are used to deposit additional material layers 410-1 and 410-2. The sputtering technique may include reactively sputtering from elemental targets with nitrogen/argon (N₂/Ar) gas mixes or non-reactively sputtering from nitride targets. A multi-cathode sputtering system may be used to perform the sputtering process. In some other embodiments, CVD, PECVD, or ALD processes can be used to deposit material layers 410-1 and 410-2.

Lining both the upper and lower surfaces of phase change layer 408 with material layers 410-1 and 410-2 provides fixed heterogenous nucleation sites on both sides of phase change layer 408 to ensure an enhanced nucleation rate regardless of whether phase change region 310 is part of an odd deck or an even deck in the memory array and/or whether crystallization proceeds from either side of the phase change layer. In some other embodiments, phase change structure 402 includes material layer 410-1 (i.e., on the top surface of phase change layer 408) and not material layer 410-2, or vice versa. In some embodiments, phase change layer 408 itself may also include a small amount of added nitrogen (e.g., less than 2% atomic weight, or between 1% and 2% atomic weight), such as proximate one or both of layers 410-1 and 410-2.

Phase change structure 404 is effectively a single continuous layer that includes a phase change material along with nitrogen at one or more locations within the phase change material. For example, the phase change layer includes at least a first region 412 that includes chalcogenide, such as GeInSbTe or GeSbTe, and no nitrogen, and one or more second regions (region 414-1 or 414-2, in this particular example case) with nitrogen added to the chalcogenide material. In some embodiments, first region 412 of the phase change layer is substantially free of nitrogen (e.g., no nitrogen is added during deposition of first region 412). In the illustrated embodiment, the phase change layer includes a top region 414-1 and a bottom region 414-2 that include nitrogen and effectively sandwich region 412 that does not include nitrogen. In other embodiments, only a single region that includes nitrogen is present on either the top or bottom of region 412 that does not include nitrogen.

In some embodiments, the phase change layer of phase change structure 404 is deposited using a sputtering process by altering the gas compositions as the material is being deposited to dynamically change the material composition of different regions of the phase change layer. For example, during deposition of chalcogenide, such as GeInSbTe or GeSbTe, the active gas (N₂) can be introduced at the beginning and at the end of the deposition to create regions 414-1 and 414-2 with the added nitrogen. According to some embodiments, CVD, PECVD, or ALD processes are used to deposit the phase change layer with dynamically changing nitrogen content during the deposition. In some embodiments, the nitrogen in region 414-1 or 414-2 is part of a refractory nitride that also includes, for example, any one of the metals Zr, Hf, Nb, Ta, Mn, or Al. The nitrogen within region 414-1 or 414-2 may have an atomic percentage between 0.25% and 2% or between 1% and 2%. In some embodiments, the amount of nitrogen present in region 414-1 or 414-2 is a catalytic amount. In some embodiments, region 412 includes a small amount of nitrogen while regions 414-1 and 414-2 each include larger amounts of nitrogen. In some embodiments, region 412 includes a graded nitrogen concentration that is lower than the nitrogen concentration in one or both of regions 414-1 and 414-2.

In some embodiments, the nitrogen content is homogenously provided within region 414-1 or 414-2. In some other embodiments, the nitrogen content is graded such that the content is highest at the edges and decreases as it moves inwards towards region 412 of the phase change layer. For example, the nitrogen content within region 414-1 may be at around 2% at a top surface of region 414-1 and around 0% at a bottom surface of region 414-1 with a steady gradient of nitrogen from 2% down to 0% moving from the top surface to the bottom surface of region 414-1. In a similar example, the nitrogen content within region 414-2 may be at around 2% at a bottom surface of region 414-2 and around 0% at a top surface of region 414-2 with a steady gradient of nitrogen from 2% down to 0% moving from the bottom surface to the top surface of region 414-2. The exact nitrogen concentrations used in the examples above are not limiting and the gradient can range between other nitrogen concentrations as well.

Phase change structure 406 includes a phase change layer 416 that includes nitrogen homogenously throughout a thickness of phase change layer 416, according to an embodiment. Phase change layer 416 may include chalcogenide, such as GeInSbTe or GeSbTe, and nitrogen. In some embodiments, the added nitrogen is part of a refractory nitride that also includes any one of the metals Zr, Hf, Nb, Ta, Mn, or Al. The nitrogen within phase change layer 416 may have an atomic percentage between 0.25% and 2% or between 1% and 2%. In some embodiments, the amount of nitrogen present in phase change layer 416 is a catalytic amount. In some embodiments, phase change layer 416 is deposited using sputtering, CVD, PECVD, or ALD and has a thickness between about 15 nm and about 25 nm.

In some embodiments, the nitrogen content within phase change layer 416 is not homogenous, but rather graded either from one surface of phase change layer 416 to the opposite surface of phase change layer 416, or from either surface of phase change layer 416 to the middle of phase change layer 416. For example, the nitrogen content within phase change layer 416 may be at around 2% at a top surface of phase change layer 416 and at a bottom surface of phase change layer 416, and at around 0.01% at the middle of phase change layer 416 with a steady gradient of nitrogen from 2% down to 0.01% moving from either the top surface or the bottom surface to the middle of phase change layer 416. The exact nitrogen concentrations used in the example above are not intended to be limiting and the gradient can range between other nitrogen concentrations as well.

In some embodiments, various regions within phase change layer 416 contain different amounts of nitrogen. One or more of the regions may be parallel to the plane of the deposited phase change region 310. One or more of the regions may be orthogonal to the plane of the deposited phase change region 310. Orthogonal regions may be formed by exposing sidewalls of phase change region 310 to a nitrogen enriched environment, thus diffusing the nitrogen into phase change region 310 through the exposed sidewalls.

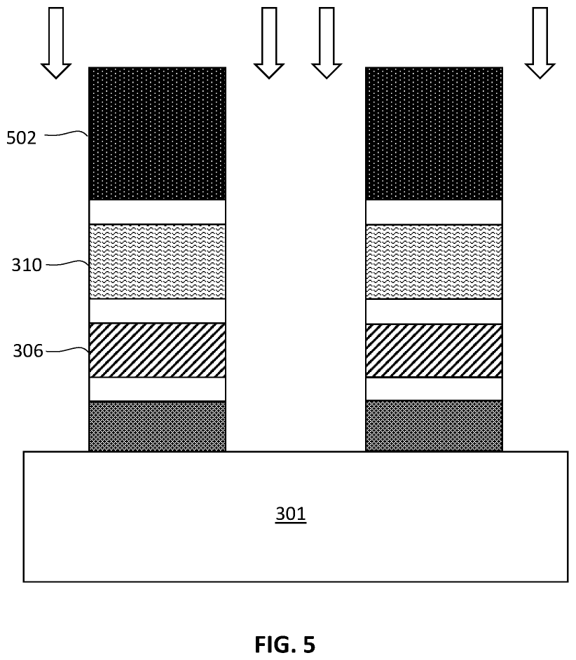

FIG. 5 illustrates an etching process being performed that etches through a thickness of at least a portion of the stack of layers to expose side walls of at least one phase change region 310 and at least one selector layer 306, according to an embodiment. A mask layer 502 may be deposited and patterned using standard lithography techniques to expose particular regions to the etching process, as variously shown in FIG. 5. Mask layer 502 may be, for example, a dielectric material, such as silicon oxide or silicon nitride. In some embodiments, the etch is carried out by a directional (anisotropic) dry etch, although wet etching can be used as well (albeit less directional) or a combination of wet and dry etching, in still other embodiments. Note that the etching process can cause, for instance, rounding of the top corners of mask layer 502 and/or rounding at the trench bottom, given real-world process limitations, as will be appreciated. The arrows indicate the general direction of a standard anisotropic dry etching process, according to one embodiment.

According to an embodiment, an anisotropic etch is performed using conventional dry etching techniques by placing substrate 301 into a vacuum chamber and introducing various gas chemistries and bias potentials to etch through the various material layers. In some embodiments, the etch process includes more than one etching procedure. For example, a first etch may be performed far enough to expose sidewalls of at least one phase change region 310, followed by depositing one or more additional films, then performing a second etch through a remainder of the layer stack down to substrate 301. The additional films deposited during the etching process are not shown for clarity but may be provided to protect at least one phase change region 310 during subsequent etching processes.

As discussed previously, in some embodiments, nitrogen may be introduced to phase change region 310 via its exposed sidewalls. The etching process illustrated in FIG. 5 forms two sidewalls on each phase change region 310 within each memory cell. According to some embodiments, the exposed sidewalls of phase change region 310 are exposed to nitrogen before any other liner structures are deposited to protect the sidewalls from further fabrication processes. Additionally, FIG. 5 illustrates one etching process for clarity, however, in some embodiments, a second etching process is performed to etch along the orthogonal direction from the first etching process to form memory cells as illustrated in FIGS. 1B and 1C. For example, the first etching process may expose a first set of sidewalls of the phase change region 310 (i.e. phase change layer 110) as illustrated in FIG. 1B while a second etching process may expose a second set of sidewalls of the phase change region 310 (i.e. phase change layer 110) as illustrated in FIG. 1C. Nitrogen may be introduced to either set of exposed sidewalls. In some examples, the concentration of nitrogen introduced to one set of sidewalls is different from the concentration of nitrogen introduced to the other set of sidewalls.

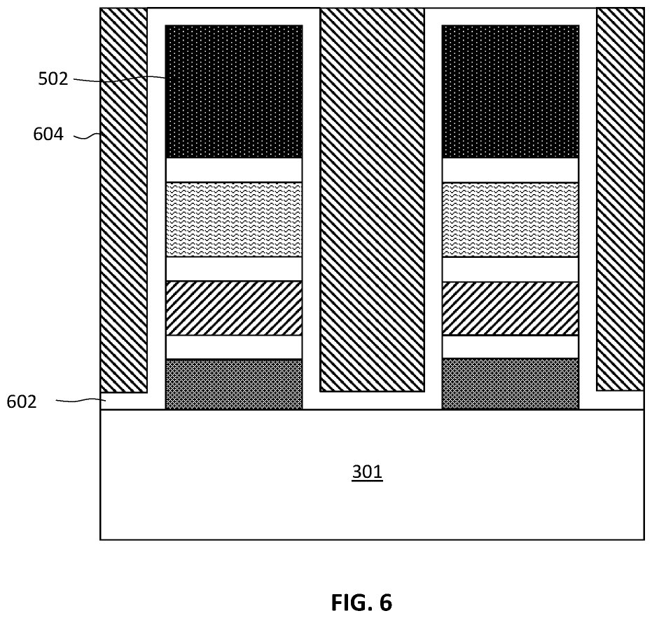

FIG. 6 illustrates the deposition of a liner structure 602 deposited to protect the various layers of each memory cell, according to some embodiments. The liner structure may include a dielectric material deposited, for example, using a low-temperature PECVD process or a low-temperature plasma enhanced atomic layer deposition (PEALD). The blanket thickness (i.e., thickness measured on a horizontal planar surface, such as the top surface of substrate 301) of liner structure 602 may be between, for example, about 30 Å and 250 Å, according to some embodiments. The thickness of liner structure 602 on the sidewalls of the memory cells may be less than the blanket thickness, depending on the conformality of the deposition technique employed. In some embodiments, liner structure 602 includes more than one deposited dielectric film. The multiple dielectric films can have the same material composition, or different material compositions depending on the application.

A fill dielectric 604 is also deposited around the various memory cells, according to an embodiment. Fill dielectric 604 is deposited over liner structure 602, in this example case. Fill dielectric 604 may be deposited to fill any remaining area between adjacent memory cells, to generally planarize the structure. In some embodiments, fill dielectric 604 is silicon oxide and is deposited using a PECVD process.

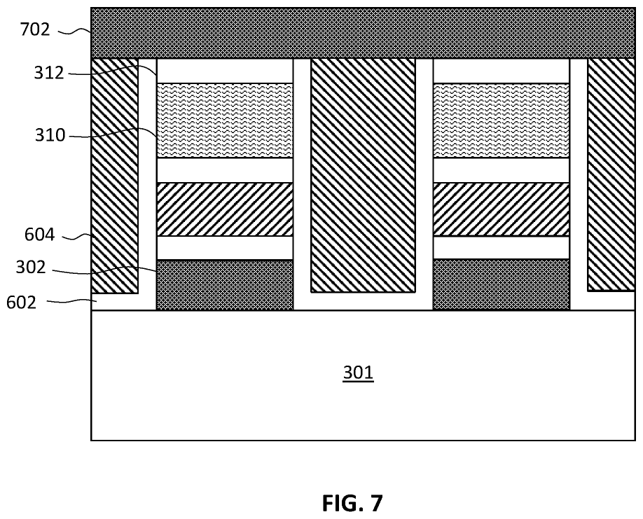

FIG. 7 illustrates the completion of a first set of memory cells, according to some embodiments. After depositing fill dielectric 604, a top surface of the structure may be planarized using a chemical mechanical polishing (CMP) process. In some embodiments, this CMP process also removes mask layer 502. In some embodiments, the structure may be planarized down to third electrode layer 312 over one or more phase change regions 310. Following the planarization, a conductive material layer 702 is deposited over the memory cells. Conductive material layer 702 may be patterned to form bit lines/word lines that run orthogonal to word lines/bit lines 302. In some embodiments, conductive material layer 702 is a metal, such as tungsten, silver, aluminum, titanium, cobalt, or an alloy.

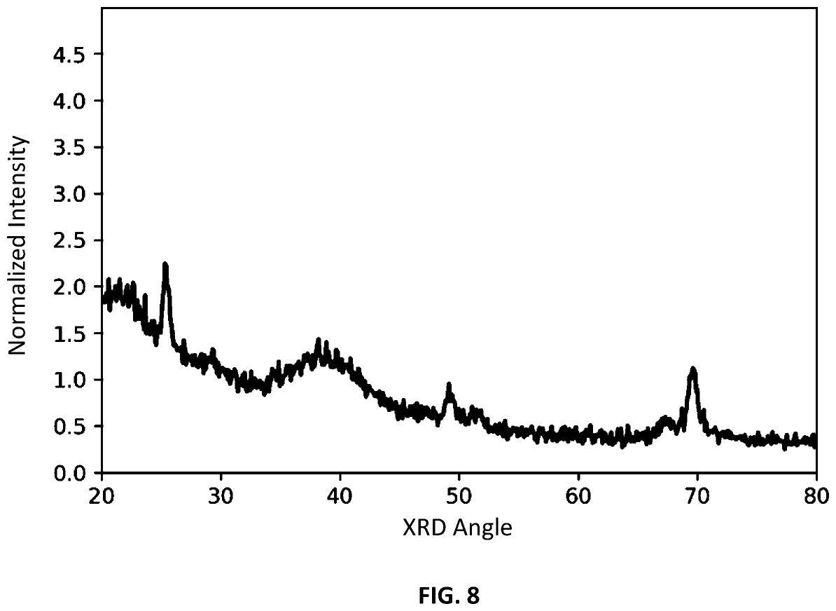

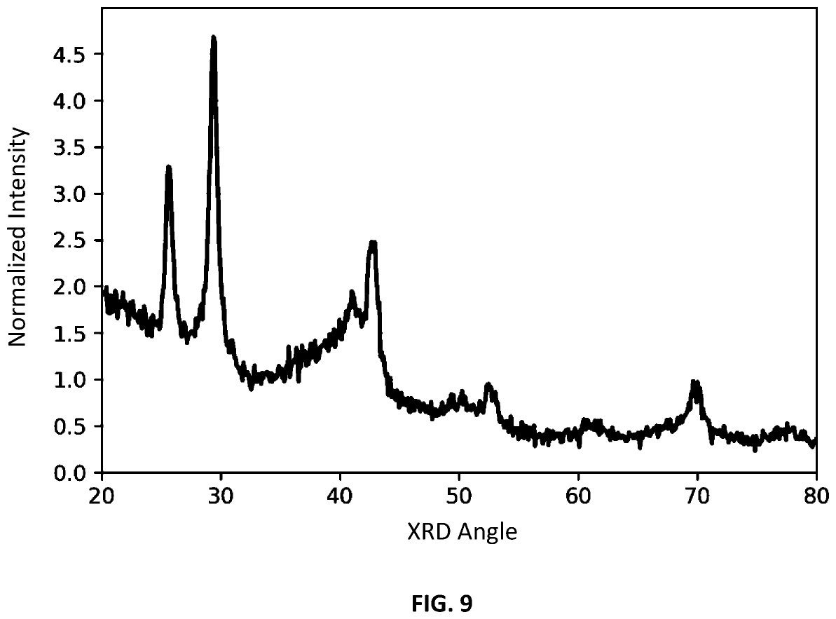

FIG. 8 illustrates X-ray diffraction (XRD) data for a phase change sample that includes GeSbTe with no added nitrogen and is deposited via sputtering at <250° C. over less than 60 seconds of deposition time. Minimal crystallization is observed in the phase change sample as seen by the lack of strong intensity peaks at any particular angles. However, FIG. 9 illustrates XRD data for another GeSbTe phase change sample deposited with reactive sputtering and a less than 1.0 sccm nitrogen flow rate at <250° C. over less than 60 seconds of deposition time, according to one example embodiment of the present disclosure. The atomic percentage of nitrogen in the phase change sample is between 0.25% and 2%. In some embodiments, the amount of nitrogen present in the phase change sample is a catalytic amount. As can be observed in FIG. 9, the introduction of a small amount of nitrogen greatly enhanced the crystallization rate and produced sharp XRD peaks consistent with high reflection off of the crystal lattice planes in the sample. The stark difference in crystallization rates may be attributed to the small concentrations of refractory nitride clusters that act as nucleation sites for the crystallization process that increases the overall crystallization rate in the sample with the added nitrogen.

Methodology

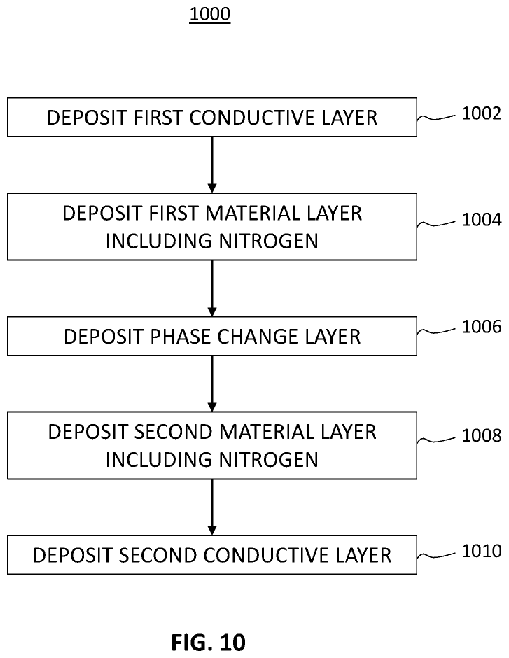

FIG. 10 is a flow chart of a method 1000 for fabricating a portion of a memory device that includes an array of memory cells having memory bit material, according to an embodiment. Various operations of method 1000 may be illustrated in FIGS. 3 and 4. However, the correlation of the various operations of method 1000 to the specific components illustrated in FIGS. 3 and 4 is not intended to imply any structural and/or use limitations. Rather, FIGS. 3 and 4 provide one example embodiment of method 1000. Other operations may be performed before, during, or after any of the operations of method 1000.

Method 1000 begins at operation 1002 where a first conductive layer is deposited over a substrate. The first conductive layer may, for example, include carbon and act as an electrode to make a better ohmic contact with a phase change region. Other suitable conductor materials can be used as well, as will be appreciated. Other layers may be present between the first conductive layer and the substrate.

Method 1000 continues with operation 1004 where a first material layer is deposited on the first conductive layer, according to an embodiment. According to an embodiment, the first material layer includes nitrogen. In some embodiments, the nitrogen in the first material layer is part of a refractory nitride that also includes any one of the metals Zr, Hf, Nb, Ta, Mn, or Al. The first material layer may be deposited using any of sputtering, CVD, PECVD, or ALD to a final thickness of less than 20 Å. In some embodiments, the nitrogen content in the first material layer is graded through a thickness of the first material layer by adjusting the nitrogen gas flow rate while depositing the first material layer. The first material layer may include between 1% and 50% atomic weight of nitrogen.

Method 1000 continues with operation 1006 where a phase change layer is deposited on the first material layer, according to an embodiment. In some embodiments, the phase change layer includes GeSbTe or GeInSbTe without any added nitrogen. In other embodiments, the phase change layer includes a small amount of nitrogen (e.g., less than 2% atomic weight). The phase change layer may be deposited using any of sputtering, CVD, PECVD, or ALD to a final thickness of between 15 nm and 25 nm.

Method 1000 continues with operation 1008 where a second material layer is deposited on the phase change layer, according to an embodiment. According to an embodiment, the second material layer includes nitrogen. In some embodiments, the nitrogen in the second material layer is part of a refractory nitride that also includes any one of the metals Zr, Hf, Nb, Ta, Mn, or Al. The second material layer may be deposited using any of sputtering, CVD, PECVD, or ALD to a final thickness of less than 20 Å. In some embodiments, the nitrogen content in the second material layer is graded through a thickness of the second material layer by adjusting the nitrogen gas flow rate while depositing the second material layer. The second material layer may include between 1% and 50% atomic weight of nitrogen. According to some embodiments, the first material layer and the second material layer have substantially the same composition (e.g., deposited using the same targets under the same conditions).

Method 1000 continues with operation 1010 where a second conductive layer is deposited on the second material layer. The second conductive layer may, for example, include carbon and act as an electrode to make a better ohmic contact with a phase change region. Other suitable conductor materials can be used as well, as will be appreciated. According to some embodiments, the first conductive layer and the second conductive layer have substantially the same composition (e.g., deposited using the same targets under the same conditions).

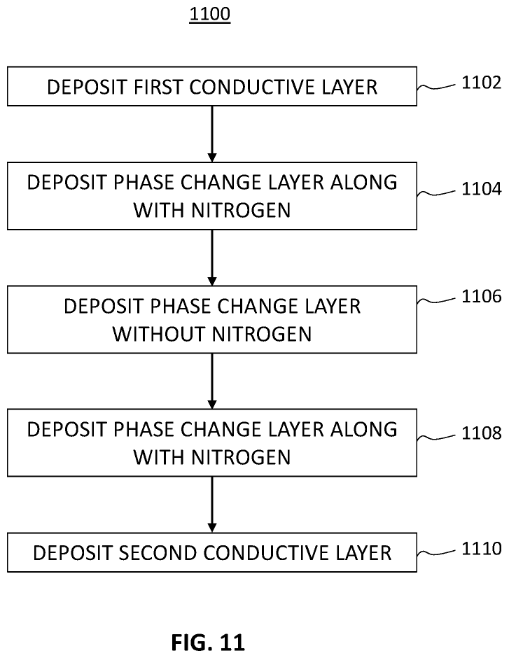

FIG. 11 is a flow chart of a method 1100 for fabricating a portion of a memory device that includes an array of memory cells having memory bit material, according to an embodiment. Various operations of method 1100 may be illustrated in FIGS. 3 and 4. However, the correlation of the various operations of method 1100 to the specific components illustrated in FIGS. 3 and 4 is not intended to imply any structural and/or use limitations. Rather, FIGS. 3 and 4 provide one example embodiment of method 1100. Other operations may be performed before, during, or after any of the operations of method 1100.

Method 1100 begins with operation 1102 where a first conductive layer is deposited over a substrate. The first conductive layer may, for example, include carbon and act as an electrode to make a better ohmic contact with a phase change region. Other suitable conductor materials can be used as well, as will be appreciated. Other layers may be present between the first conductive layer and the substrate.

Method 1100 continues with operations 1104, 1106, and 1108 which may be considered to be separate stages of a single deposition process of a phase change layer on the first conductive layer, according to some embodiments. According to some embodiments, sputtering, CVD, PECVD, or ALD processes are used to deposit the phase change layer with dynamically changing nitrogen content during the deposition.

Operation 1104 includes depositing a phase change layer of GeSbTe or GeInSbTe along with added nitrogen. In some embodiments, the added nitrogen is part of a refractory nitride that also includes any one of the metals Zr, Hf, Nb, Ta, Mn, or Al. The nitrogen may have an atomic percentage between 0.25% and 2%. The nitrogen may be added at a constant flow rate throughout operation 1104 or increased/decreased throughout the deposition to provide a gradient of nitrogen content in a first portion of the phase change layer.

Operation 1106 continues the deposition of the phase change layer without the nitrogen, according to an embodiment. In some embodiments, operation 1106 continues the deposition of the phase change layer having a smaller nitrogen concentration than any portion of the phase change layer deposited in operation 1104.

Operation 1108 continues the deposition of the phase change layer with added nitrogen (or increased nitrogen), according to an embodiment. In some embodiments, the added nitrogen is part of a refractory nitride that also includes any one of the metals Zr, Hf, Nb, Ta, Mn, or Al. The nitrogen may have an atomic percentage between 0.25% and 2%. The nitrogen may be added at a constant flow rate throughout operation 1108 or increased/decreased throughout the deposition to provide a gradient of nitrogen content in a second portion of the phase change layer.

Method 1100 continues with operation 1110 where a second conductive layer is deposited on the phase change layer. The second conductive layer may, for example, include carbon and act as an electrode to make a better ohmic contact with a phase change region. Other suitable conductor materials can be used as well, as will be appreciated. According to some embodiments, the first conductive layer and the second conductive layer have substantially the same composition (e.g., deposited using the same targets under the same conditions).

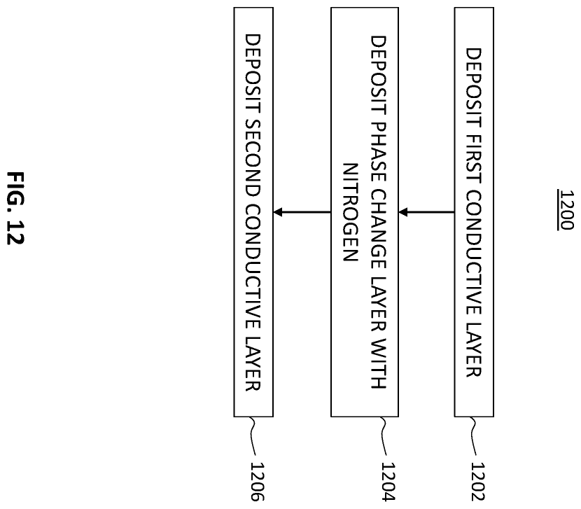

FIG. 12 is a flow chart of a method 1200 for fabricating a portion of a memory device that includes an array of memory cells having memory bit material, according to an embodiment. Various operations of method 1200 may be illustrated in FIGS. 3 and 4. However, the correlation of the various operations of method 1200 to the specific components illustrated in FIGS. 3 and 4 is not intended to imply any structural and/or use limitations. Rather, FIGS. 3 and 4 provide one example embodiment of method 1200. Other operations may be performed before, during, or after any of the operations of method 1200.

Method 1200 begins with operation 1202 where a first conductive layer is deposited over a substrate. The first conductive layer may, for example, include carbon and act as an electrode to make a better ohmic contact with a phase change region. Other suitable conductor materials can be used as well, as will be appreciated. Other layers may be present between the first conductive layer and the substrate.

Method 1200 continues with operation 1204 where a phase change layer including chalcogenide, such as GeInSbTe or GeSbTe, and nitrogen is deposited on the first conductive layer, according to some embodiments. In some embodiments, the nitrogen is homogenously dispersed throughout an entire thickness of the deposited phase change layer. In some embodiments, the nitrogen content within the phase change layer is graded either from one surface of the phase change layer to the opposite surface of the phase change layer, or from either surface of the phase change layer to the middle of the phase change layer. In some embodiments, the added nitrogen is part of a refractory nitride that also includes any one of the metals Zr, Hf, Nb, Ta, Mn, or Al. The nitrogen within the phase change layer may have an atomic percentage between 0.25% and 2%. The phase change layer may be deposited using any one of sputtering, CVD, PECVD, or ALD processes with nitrogen gas added during the deposition to a final thickness between about 15 nm and about 25 nm.

Method 1200 continues with operation 1206 where a second conductive layer is deposited on the phase change layer. The second conductive layer may, for example, include carbon and act as an electrode to make a better ohmic contact with a phase change region. Other suitable conductor materials can be used as well, as will be appreciated. According to some embodiments, the first conductive layer and the second conductive layer have substantially the same composition (e.g., deposited using the same targets under the same conditions).

Example Electronic Device

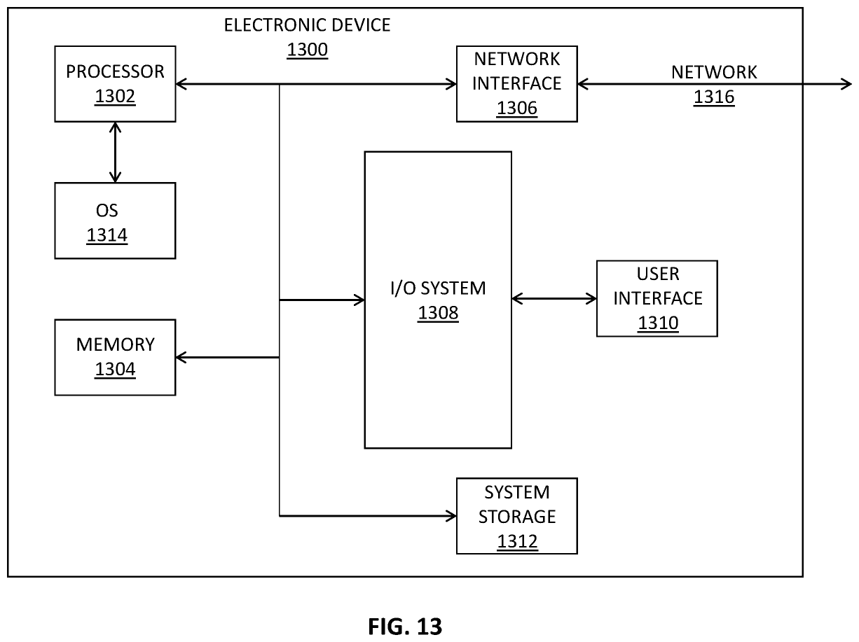

FIG. 13 illustrates an example electronic device 1300 that may include one or more memory devices such as the embodiments disclosed herein. In some embodiments, electronic device 1300 may host, or otherwise be incorporated into a personal computer, workstation, server system, laptop computer, ultra-laptop computer, tablet, touchpad, portable computer, handheld computer, palmtop computer, personal digital assistant (PDA), cellular telephone, combination cellular telephone and PDA, smart device (for example, smartphone or smart tablet), mobile internet device (MID), messaging device, data communication device, imaging device, wearable device, embedded system, and so forth. Any combination of different devices may be used in certain embodiments.

In some embodiments, electronic device 1300 may comprise any combination of a processor 1302, a memory 1304, a network interface 1306, an input/output (I/O) system 1308, a user interface 1310, and a storage system 1312. As can be further seen, a bus and/or interconnect is also provided to allow for communication between the various components listed above and/or other components not shown. Electronic device 1300 can be coupled to a network 1316 through network interface 1306 to allow for communications with other computing devices, platforms, or resources. Other componentry and functionality not reflected in the block diagram of FIG. 13 will be apparent in light of this disclosure, and it will be appreciated that other embodiments are not limited to any particular hardware configuration.

Processor 1302 can be any suitable processor and may include one or more coprocessors or controllers to assist in control and processing operations associated with electronic device 1300. In some embodiments, processor 1302 may be implemented as any number of processor cores. The processor (or processor cores) may be any type of processor, such as, for example, a micro-processor, an embedded processor, a digital signal processor (DSP), a graphics processor (GPU), a network processor, a field programmable gate array or other device configured to execute code. The processors may be multithreaded cores in that they may include more than one hardware thread context (or “logical processor”) per core.

Memory 1304 can be implemented using any suitable type of digital storage including, for example, flash memory and/or random access memory (RAM). In some embodiments, memory 1304 may include various layers of memory hierarchy and/or memory caches as are known to those of skill in the art. Memory 1304 may be implemented as a volatile memory device such as, but not limited to, a RAM, dynamic RAM (DRAM), or static RAM (SRAM) device. Storage system 1312 may be implemented as a non-volatile storage device such as, but not limited to, one or more of a hard disk drive (HDD), a solid-state drive (SSD), a universal serial bus (USB) drive, an optical disk drive, tape drive, an internal storage device, an attached storage device, flash memory, battery backed-up synchronous DRAM (SDRAM), and/or a network accessible storage device. In some embodiments, storage system 1312 may comprise technology to increase the storage performance enhanced protection for valuable digital media when multiple hard drives are included. According to some embodiments of the present disclosure, either or both memory 1304 and storage system 1312 includes one or more memory arrays 122 having memory cells 102 fabricated using one or more of the processes discussed herein. According to some embodiments of the present disclosure, either or both memory 1304 and storage system 1312 may be incorporated in a chip package 200 and bonded to a printed circuit board (PCB) along with one or more other devices.

Processor 1302 may be configured to execute an Operating System (OS) 1314 which may comprise any suitable operating system, such as Google Android (Google Inc., Mountain View, Calif.), Microsoft Windows (Microsoft Corp., Redmond, Wash.), Apple OS X (Apple Inc., Cupertino, Calif.), Linux, or a real-time operating system (RTOS), and/or any other executable applications. Processor 1302 may also include onboard cache or memory that can be configured, for instance, with memory array structures as variously provided herein.

Network interface 1306 can be any appropriate network chip or chipset which allows for wired and/or wireless connection between other components of electronic device 1300 and/or network 1316, thereby enabling electronic device 1300 to communicate with other local and/or remote computing systems, servers, cloud-based servers, and/or other resources. Wired communication may conform to existing (or yet to be developed) standards, such as, for example, Ethernet. Wireless communication may conform to existing (or yet to be developed) standards, such as, for example, cellular communications including LTE (Long Term Evolution), Wireless Fidelity (Wi-Fi), Bluetooth, and/or Near Field Communication (NFC). Exemplary wireless networks include, but are not limited to, wireless local area networks, wireless personal area networks, wireless metropolitan area networks, cellular networks, and satellite networks.

I/O system 1308 may be configured to interface between various I/O devices and other components of electronic device 1300. I/O devices may include, but not be limited to, a user interface 1310. User interface 1310 may include devices (not shown) such as a display element, touchpad, keyboard, mouse, and speaker, etc. I/O system 1308 may include a graphics subsystem configured to perform processing of images for rendering on a display element. Graphics subsystem may be a graphics processing unit or a visual processing unit (VPU), for example. An analog or digital interface may be used to communicatively couple graphics subsystem and the display element. For example, the interface may be any of a high definition multimedia interface (HDMI), DisplayPort, wireless HDMI, and/or any other suitable interface using wireless high definition compliant techniques. In some embodiments, the graphics subsystem could be integrated into processor 1302 or any chipset of electronic device 1300.

It will be appreciated that in some embodiments, the various components of the electronic device 1300 may be combined or integrated in a system-on-a-chip (SoC) architecture. In some embodiments, the components may be hardware components, firmware components, software components or any suitable combination of hardware, firmware or software.

In various embodiments, electronic device 1300 may be implemented as a wireless system, a wired system, or a combination of both. When implemented as a wireless system, electronic device 1300 may include components and interfaces suitable for communicating over a wireless shared media, such as one or more antennae, transmitters, receivers, transceivers, amplifiers, filters, control logic, and so forth. An example of wireless shared media may include portions of a wireless spectrum, such as the radio frequency spectrum and so forth. When implemented as a wired system, electronic device 1300 may include components and interfaces suitable for communicating over wired communications media, such as input/output adapters, physical connectors to connect the input/output adaptor with a corresponding wired communications medium, a network interface card (NIC), disc controller, video controller, audio controller, and so forth. Examples of wired communications media may include a wire, cable metal leads, printed circuit board (PCB), backplane, switch fabric, semiconductor material, twisted pair wire, coaxial cable, fiber optics, and so forth.

Unless specifically stated otherwise, it may be appreciated that terms such as “processing,” “computing,” “calculating,” “determining,” or the like refer to the action and/or process of a computer or computing system, or similar electronic computing device, that manipulates and/or transforms data represented as physical quantities (for example, electronic) within the registers and/or memory units of the computer system into other data similarly represented as physical quantities within the registers, memory units, or other such information storage transmission or displays of the computer system. The embodiments are not limited in this context.

### Further Example Embodiments

The following examples pertain to further embodiments, from which numerous permutations and configurations will be apparent.

Example 1 is a memory device that includes a plurality of conductive bit lines, including a first bit line and a second bit line, a plurality of conductive word lines, including a first word line and a second word line, and a set of memory cells included in a memory array. The set of memory cells includes first and second memory cells. The first memory cell is between the first bit line and the first word line, and the second memory cell is between the second bit line and the second word line. Each of the first and second memory cells includes a stack of layers comprising a phase change layer, wherein one or more of the phase change layers includes nitrogen.

Example 2 includes the subject matter of Example 1, wherein the plurality of conductive bit lines run orthogonal to the plurality of conductive word lines.

Example 3 includes the subject matter of Example 1 or 2, wherein the memory cell array is arranged in three dimensions with memory cells positioned in rows and columns along a plurality of XY planes stacked in a Z direction.

Example 4 includes the subject matter of any one of Examples 1-3, wherein the one or more of the phase change layers comprises a chalcogenide material.

Example 5 includes the subject matter of any one of Examples 1-4, wherein the one or more of the phase change layers comprises two or more of germanium (Ge), indium (In), antimony (Sb), and tellurium (Te).

Example 6 includes the subject matter of any one of Examples 1-5, wherein the one or more of the phase change layers includes the nitrogen homogeneously throughout a thickness of the one or more of the phase change layers.

Example 7 includes the subject matter of any one of Examples 1-5, wherein a thickness of the one or more of the phase change layers includes a first portion having the nitrogen, a second portion that is free of nitrogen, and a third portion having the nitrogen, and wherein the second portion is under the first portion and above the third portion.

Example 8 includes the subject matter of Example 7, wherein the first portion and the third portion each comprises about 2% atomic weight of nitrogen.

Example 9 includes the subject matter of any one of Examples 1-8, wherein the one or more of the phase change layers further includes one or more of zirconium (Zr), hafnium (Hf), niobium (Nb), tantalum (Ta), manganese (Mn), aluminum (Al), germanium (Ge), or silicon (Si).

Example 10 includes the subject matter of any one of Examples 1-9, wherein the one or more of the phase change layers includes less than about 2% atomic weight of nitrogen.

Example 11 includes the subject matter of any one of Examples 1-10, wherein the one or more of the phase change layers includes a graded nitrogen concentration.

Example 12 includes the subject matter of Example 11, wherein the nitrogen concentration is highest at a top interface of the one or more of the phase change layers.

Example 13 includes the subject matter of Example 11, wherein the nitrogen concentration is highest at a bottom interface of the one or more of the phase change layers.

Example 14 includes the subject matter of any one of Examples 1-13, wherein the one or more of the phase change layers includes one or more regions that are orthogonal to planes of the plurality of conductive bit lines and the plurality of conductive word lines, the one or more regions comprising varying concentrations of nitrogen.

Example 15 includes the subject matter of Example 14, wherein at least one of the one or more regions is present at a sidewall of the one or more of the phase change layers.

Example 16 is an integrated circuit comprising the memory device of any one of Examples 1-15.

Example 17 is a printed circuit board comprising the integrated circuit of Example 16.

Example 18 is a memory chip comprising the memory device of any one of Examples 1-15.

Example 19 is a memory device having a plurality of conductive bit lines, including a first bit line and a second bit line, a plurality of conductive word lines, including a first word line and a second word line, and a set of memory cells included in a memory cell array. The set of memory cells includes first and second memory cells. The first memory cell is between the first bit line and the first word line, and the second memory cell is between the second bit line and the second word line. Each of the first and second memory cells includes a phase change structure having a first layer and a second layer where the first layer includes a phase change material and the second layer includes nitrogen. Each of the first and second memory cells also includes a third layer comprising a conductive material. The second layer is between the third layer and the first layer.

Example 20 includes the subject matter of Example 19, wherein the plurality of conductive bit lines run orthogonal to the plurality of conductive word lines.

Example 21 includes the subject matter of Example 19 or 20, wherein the memory cell array is arranged in three dimensions with memory cells positioned in rows and columns along a plurality of XY planes stacked in a Z direction.

Example 22 includes the subject matter of any one of Examples 19-21, wherein the phase change material of the first layer comprises a chalcogenide material.

Example 23 includes the subject matter of any one of Examples 19-22, wherein the phase change material of the first layer comprises two or more of germanium (Ge), indium (In), antimony (Sb), and tellurium (Te).

Example 24 includes the subject matter of any one of Examples 19-23, wherein the second layer includes between about 1% and about 50% atomic weight of nitrogen.

Example 25 includes the subject matter of any one of Examples 19-24, wherein the second layer further includes one or more of zirconium (Zr), hafnium (Hf), niobium (Nb), tantalum (Ta), manganese (Mn), aluminum (Al), germanium (Ge), or silicon (Si).

Example 26 includes the subject matter of any one of Examples 19-25, wherein the second layer is a first nitrogen-containing layer on a first surface of the phase change material of the first layer, and the phase change structure comprises a second nitrogen-containing layer on a second surface of the phase change material of the first layer that is opposite to the first surface.

Example 27 includes the subject matter of Example 26, wherein the first nitrogen-containing layer has the same composition as the second nitrogen-containing layer.

Example 28 includes the subject matter of any one of Examples 19-27, wherein the phase change material of the first layer includes less than about 2% atomic weight of nitrogen.

Example 29 includes the subject matter of any one of Examples 19-28, wherein the second layer has a thickness of less than about 20 Å.

Example 30 includes the subject matter of any one of Examples 19-29, wherein the conductive material of the third layer comprises carbon.

Example 31 is an integrated circuit comprising the memory device of any one of Examples 19-30.

Example 32 is a printed circuit board comprising the integrated circuit of Example 31.

Example 33 is a memory chip comprising the memory device of any one of Examples 19-30.

Example 34 is an electronic device having a chip package with one or more dies. At least one of the one or more dies includes a stack of layers between a word line and a bit line. The stack of layers comprises a phase change layer that includes nitrogen.

Example 35 includes the subject matter of Example 34, wherein the phase change layer comprises a chalcogenide material.

Example 36 includes the subject matter of Example 34 or 35, wherein the phase change layer comprises two or more of germanium (Ge), indium (In), antimony (Sb), and tellurium (Te).

Example 37 includes the subject matter of any one of Examples 34-36, wherein the phase change layer includes the nitrogen homogeneously throughout a thickness of the phase change layer.

Example 38 includes the subject matter of any one of Examples 34-37, wherein a thickness of the phase change layer includes a first portion having the nitrogen and a second portion that is substantially free of nitrogen.

Example 39 includes the subject matter of any one of Examples 34-38, wherein a thickness of the phase change layer includes a first portion having the nitrogen, a second portion that is free of nitrogen, and a third portion having the nitrogen, and wherein the second portion is under the first portion and above the third portion.

Example 40 includes the subject matter of any one of Examples 34-39, wherein the first portion and the third portion each comprises about 2% atomic weight of nitrogen.

Example 41 includes the subject matter of any one of Examples 34-40, wherein the phase change layer further includes one or more of zirconium (Zr), hafnium (Hf), niobium (Nb), tantalum (Ta), manganese (Mn), aluminum (Al), germanium (Ge), or silicon (Si).

Example 42 includes the subject matter of any one of Examples 34-41, wherein the phase change layer includes less than about 2% atomic weight of nitrogen.

Example 43 includes the subject matter of any one of Examples 34-42, wherein the phase change layer includes a graded nitrogen concentration.

Example 44 includes the subject matter of Example 43, wherein the nitrogen concentration is highest at a top interface of the phase change layer.

Example 45 includes the subject matter of Example 43, wherein the nitrogen concentration is highest at a bottom interface of the phase change layer.

Example 46 includes the subject matter of any one of Examples 34-45, wherein the phase change layer includes one or more regions that are orthogonal to planes of the bit line and the word line, the one or more regions comprising varying concentrations of nitrogen.

Example 47 includes the subject matter of Example 46, wherein at least one of the one or more regions is present at a sidewall of the phase change layer.

Example 48 is an electronic device having a chip package with one or more dies. At least one of the one or more dies includes a phase change structure between a word line and a bit line. The phase change structure includes a first layer and a second layer where the first layer includes nitrogen and the second layer includes a phase change material. The one or more dies also includes a third layer having a conductive material. The first layer is between the second layer and third layer in a stacked configuration.

Example 49 includes the subject matter of Example 48, wherein the phase change material of the second layer comprises a chalcogenide material.

Example 50 includes the subject matter of Example 48 or 49, wherein the phase change material of the second layer comprises two or more germanium (Ge), indium (In), antimony (Sb), and tellurium (Te).

Example 51 includes the subject matter of any one of Examples 48-50, wherein the first layer includes between about 1% and about 50% atomic weight of nitrogen.

Example 52 includes the subject matter of any one of Examples 48-51, wherein the first layer further includes one or more of zirconium (Zr), hafnium (Hf), niobium (Nb), tantalum (Ta), manganese (Mn), aluminum (Al), germanium (Ge), or silicon (Si).

Example 53 includes the subject matter of any one of Examples 48-52, wherein the first layer is a first nitrogen-containing layer on a first surface of the phase change material of the second layer, and the phase change structure further comprises a second nitrogen-containing layer on a second surface of the phase change material of the second layer that is opposite to the first surface of the second layer.

Example 54 includes the subject matter of Example 53, wherein the first nitrogen-containing layer has the same composition as the second nitrogen-containing layer.

Example 55 includes the subject matter of any one of Examples 48-54, wherein the phase change material of the second layer includes less than about 2% atomic weight of nitrogen.

Example 56 includes the subject matter of any one of Examples 48-55, wherein the first layer has a thickness of less than about 20 Å.

Example 57 includes the subject matter of any one of Examples 48-56, wherein the third layer comprises carbon.

Example 58 includes the subject matter of any one of Examples 48-57, wherein the first layer includes a graded nitrogen concentration.

Numerous specific details have been set forth herein to provide a thorough understanding of the embodiments. It will be understood in light of this disclosure, however, that the embodiments may be practiced without these specific details. In other instances, well known operations, components and circuits have not been described in detail so as not to obscure the embodiments. It can be appreciated that the specific structural and functional details disclosed herein may be representative and do not necessarily limit the scope of the embodiments. In addition, although the subject matter has been described in language specific to structural features and/or methodological acts, it is to be understood that the subject matter defined in the appended claims is not necessarily limited to the specific features or acts described herein. Rather, the specific features and acts described herein are disclosed as example forms of implementing the claims.

What is claimed is:

1. A memory device, comprising:
a plurality of conductive bit lines, including a first bit line and a second bit line;
a plurality of conductive word lines, including a first word line and a second word line;
a set of memory cells included in a memory cell array, the set of memory cells including first and second memory cells, the first memory cell between the first bit line and the first word line, and the second memory cell between the second bit line and the second word line, each of the first and second memory cells comprising a stack of layers comprising a phase change layer, wherein one or more of the phase change layers includes nitrogen.

2. The memory device of claim 1, wherein the memory cell array is arranged in three dimensions with memory cells positioned in rows and columns along a plurality of XY planes stacked in a Z direction.

3. The memory device of claim 1, wherein the one or more of the phase change layers comprises a chalcogenide material.

4. The memory device of claim 1, wherein the one or more of the phase change layers includes less than about 2% atomic weight of nitrogen.

5. The memory device of claim 1, wherein the one or more of the phase change layers includes a graded nitrogen concentration.

6. The memory device of claim 1, wherein the one or more of the phase change layers includes one or more regions that are orthogonal to planes of the plurality of conductive bit lines and the plurality of conductive word lines, the one or more regions comprising varying concentrations of nitrogen.

7. The memory device of claim 6, wherein at least one of the one or more regions is present at a sidewall of the one or more of the phase change layers.

8. A memory device, comprising:
a plurality of conductive bit lines, including a first bit line and a second bit line;
a plurality of conductive word lines, including a first word line and a second word line; and
a set of memory cells included in a memory cell array, the set of memory cells including first and second memory cells, the first memory cell between the first bit line and the first word line, and the second memory cell between the second bit line and the second word line, each of the first and second memory cells comprising
a phase change structure having a first layer and a second layer, the first layer comprising a phase change material and the second layer comprising nitrogen, and
a third layer comprising a conductive material, wherein the second layer is between the third layer and the first layer.

9. The memory device of claim 8, wherein the memory cell array is arranged in three dimensions with memory cells positioned in rows and columns along a plurality of XY planes stacked in a Z direction.

10. The memory device of claim 8, wherein the phase change material of the first layer comprises a chalcogenide material.

11. The memory device of claim 8, wherein the second layer includes between about 1% and about 50% atomic weight of nitrogen.

12. The memory device of claim 8, wherein the second layer is a first nitrogen-containing layer on a first surface of the phase change material of the first layer, and the phase change structure comprises a second nitrogen-containing layer on a second surface of the phase change material of the first layer that is opposite to the first surface.

13. The memory device of claim 12, wherein the first nitrogen-containing layer has the same composition as the second nitrogen-containing layer.

14. The memory device of claim 8, wherein the phase change material of the first layer includes less than about 2% atomic weight of nitrogen.

15. An electronic device, comprising:
a chip package comprising one or more dies, at least one of the one or more dies comprising
a stack of layers between a word line and a bit line, the stack of layers comprising a phase change layer, wherein the phase change layer includes nitrogen.

16. The electronic device of claim 15, wherein the phase change layer comprises a chalcogenide material.

17. The electronic device of claim 15, wherein a thickness of the phase change layer includes a first portion having the nitrogen, a second portion that is free of nitrogen, and a third portion having the nitrogen, and wherein the second portion is under the first portion and above the third portion.

18. The electronic device of claim 15, wherein the phase change layer includes less than about 2% atomic weight of nitrogen.

19. The electronic device of claim 15, wherein the phase change layer includes a graded nitrogen concentration.

20. The electronic device of claim 15, wherein the phase change layer includes one or more regions that are orthogonal to planes of the bit line and the word line, the one or more regions comprising varying concentrations of nitrogen.
